(19) United States
(12) Patent Application Publication
(10) Pub. No.: US 2009/0298219 A1
(43) Pub. Date: Dec. 3, 2009

(54) Method for Manufacturing Solid-State Image Pickup Device Module

(75) Inventors: Takayuki Ohmoto, Fukuyama-shi , Hiroshima (JP); Toshihiro Fujii, Kasaoka-shi , Okayama (JP); Aiji Suetake, Fukuyama-shi Hiroshima (JP); Hajime Oda, Okayama-shi ,Okayama (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 12/087,146

(22) PCT Filed: Dec. 14, 2006
(86) PCT No.: PCT/JP2006/324920

§ 371 Date: Jun. 30, 2009

(30) Foreign Application Priority Data
Dec. 26, 2005 (JP) 2005-373484

(51) Int. Cl. H01L 31/18

(52) U.S. Cl. 438/66; 438/68; 257/E31.11; 438/69

(57) ABSTRACT

A method for manufacturing a solid-state pickup device module of the present invention includes: a step of processing a transparent substrate so that each of transparent substrates for a chip is held opposite to each of solid-state image pickup devices when the transparent substrate and a substrate having a plurality of solid-state image pickup devices are opposed to each other (step of processing a transparent substrate; S1 to S17); and a modularizing step in which the transparent substrate thus processed and the substrate having a plurality of solid-state image pickup devices are opposed to each other so as to place each of the transparent substrates for a chip opposite to each of the solid-state image pickup devices (modularizing step; S21 to S28). Thus, the present invention can improve manufacturing efficiency by bonding the transparent substrate and the substrate having a plurality of solid-state image pickup devices at a time. In addition, the present invention provides a method for manufacturing a solid-state image pickup device module whereby a wafer can be easily cut.

### TECHNICAL FIELD

The present invention relates to a method for manufacturing a solid-state image pickup device module which is modularized by attaching other members such as a transparent substrate to a solid-state image pickup device formed on a substrate.

### BACKGROUND ART

Conventionally, manufacturing step of a solid-state image pickup device module includes a step of providing a transparent substrate. The step of providing a transparent substrate is a step in which a sealing agent is provided around a semiconductor region of a solid-state image pickup device, and then a transparent substrate (made of glass, for example) is provided on the sealing agent so as to face the solid-state image pickup device. The following first through third methods have been already suggested with regard to the step of providing a transparent substrate.

In the first method, a wafer having a plurality of solid-state image pickup devices is diced into solid-state image pickup device chips in advance. A transparent substrate is cut into individual transparent substrates in advance so that the individual transparent substrates have a proper size when they are provided to the solid-state image pickup device. After applying the sealing agent around the semiconductor region of the solid-state image pickup device, the solid-state image pickup devices and the individual transparent substrates are provided so as to face each other one-on-one.

In the second method, a transparent substrate is cut into a plurality of individual transparent substrates so that the transparent substrates have a proper size when they are provided to a solid-state image pickup device, whereas the solid-state image pickup device is not diced but remains a wafer. After applying a sealing agent around the semiconductor region of the solid-state image pickup device, the solid-state image pickup devices and the individual transparent substrates are provided so as to face, respectively, and be combined with each other. The wafer is finally diced.

In the third method, a wafer on which a plurality of solid-state image pickup devices are formed and a wafer-like transparent substrate are prepared. A sealing agent is applied around a semiconductor region of each of the solid-state image pickup devices formed on the wafer. Each of the solid-state image pickup devices and a respective one of the transparent substrates, which remain in a wafer shape, are combined with each other. The solid-state image pickup devices and the transparent substrates are finally diced into chips at a time. The third method is disclosed in, for example, Patent Document 1.

When comparing the methods, the first and second methods require inevitably a longer takt time because the transparent substrates (made of glass) are not combined with the solid-state image pickup devices at a time (namely, the wafer-like transparent substrate is not used). This causes the first and second methods to have low manufacturing efficiency. In contrast, according to the third method, the transparent substrates are combined with the solid-state image pickup device, respectively (the wafer-like transparent substrate is used). This makes a takt time shorter. Accordingly, the third method is superior to the first and second methods in manufacturing efficiency.

[Patent Document 1] Japanese Unexamined Patent Publication 2004-296738 (Tokukai 2004-296738 (published on Oct. 21, 2004))

### DISCLOSURE OF INVENTION

Note however that, when the third method is tried to be actually carried out, it is necessary to carry out a step of cutting at a time (i) a wafer on which a plurality of solid-state image pickup devices are formed and (ii) a wafer-like transparent substrate (cutting step). However, such a cutting step turned out not to be easy to perform, and turned out that the wafer and the wafer-like transparent substrate were not cut properly when the cutting step is actually carried out.

In view of the problem, an object of the present invention is to provide a method for manufacturing a solid-state image pickup device module, in which method (i) manufacturing efficiency is improved and (ii) cutting can be easily and properly carried out after a substrate on which a plurality of solid-state image pickup devices are formed and a transparent substrate are combined with each other, by combining, in a lump, the plurality of solid-state image pickup devices with the transparent substrate.

In order to attain the object, a method for manufacturing a solid-state image pickup device module, the method of the present invention includes the steps of: processing a transparent substrate so that individual transparent substrates and solid-state image pickup devices face and are held, respectively, when the transparent substrate and a substrate having the solid-state image pickup devices face each other; and causing the transparent substrate thus processed and the substrate having the solid-state image pickup devices to be arranged so that the individual transparent substrates face the solid-state image pickup devices, respectively.

In addition, a method for manufacturing a solid-state image pickup device module, the method includes the steps of: cutting a transparent substrate so that individual transparent substrates are prepared, which are arranged to face solid-state image pickup devices, respectively; applying a sealing agent on a first substrate so that the sealing agent is applied around the solid-state image pickup devices which the first substrate includes; causing said first substrate on which the sealing agent is applied and a second substrate holding the individual transparent substrates to be arranged so that the individual transparent substrates face the solid-state image pickup devices, respectively; curing the sealing agent; and dividing said first substrate after curing the sealing agent.

As a result, the methods do not cause a problem that the cutting step becomes difficult to perform because the transparent substrate and the substrate having the solid-state image pickup devices are individually cut, namely, the methods do not include a step of cutting both substrates at a time, unlike Patent Document 1. Furthermore, manufacturing efficiency as to bonding does not decrease because the transparent substrates for a chip are bonded onto the substrate having the solid-state image pickup devices, collectively by substrate.

In the present invention, a method for manufacturing a solid-state image pickup device module, includes the steps of: dividing a substrate having a plurality of solid-state image pickup devices into solid-state image pickup device chips; aligning and holding the solid-state image pickup device chips on a dummy substrate; applying a sealing agent around each of the solid-state image pickup devices on the dummy substrate; cutting a transparent substrate so that individual transparent substrates are prepared, which are arranged to face solid-state image pickup devices, respectively; and causing (i) the dummy substrate having the solid-state image pickup device chips, which have been aligned and held and around each of which the sealing agent has been applied and (ii) a substrate holding the individual transparent substrates to face each other so that the individual transparent substrates face the solid-state image pickup devices, respectively.

Likewise, according to the method, the transparent substrate is cut in advance. Accordingly, the methods as well as that of Patent Document 1 do not include a step of cutting at a time the transparent substrate and the substrate having the solid-state image pickup devices. As a result, the methods do not cause a problem that the step of cutting becomes difficult to perform. In addition, manufacturing efficiency as to bonding does not decrease because the transparent substrates for a chip are bonded onto the substrate having the solid-state image pickup devices, collectively by substrate. Furthermore, the step of cutting can be omitted after bonding the transparent substrate onto the substrate having the solid-state image pickup devices. Accordingly, dust etc. due to the step of cutting do not easily enter into the solid-state image pickup device module. As a result, a yield can be improved.

Moreover, with respect to a chip which has been bonded onto the transparent substrate, product failures due to a step before bonding can be prevented in such a manner that, before a step of bonding the transparent substrate onto the substrate having the solid-state image pickup devices, the substrate having the solid-state image pickup devices is separated into the solid-state image pickup device chips, thereafter only non-defective solid-state image pickup device chips being arrayed on the dummy substrate. As a result, a yield as to the step of bonding can be improved.

In the present invention, it is preferable that the method for manufacturing a solid-state image pickup device module further includes the step of: temporarily fixing a support to the transparent substrate, before the step of cutting the transparent substrate, wherein the support and the transparent substrate are temporarily fixed to each other via an adhesive whose adhesion is decreased in response to externally applied force. This makes it possible to easily strip a supporting substrate from the solid-state image pickup device chip. As a result, defects due to bonding are less likely caused.

In a case where the step of aligning/holding solid-state image pickup device chips is included, the dummy substrate can be easily stripped from the solid-state image pickup device chip when the dummy substrate and the solid-state image pickup device chip are temporarily bonded with each other with an adhesive whose adherability is decreased by applying external forces thereto. As a result, defects due to bonding are less likely caused.

In the present invention, in particular, a foaming agent that generates bubbles by applying ultraviolet rays or heat or a material that is hardened by applying ultraviolet rays or heat, thereby adherability of the material being decreased can be suitably used for the adhesive whose adherability is decreased by applying external forces thereto.

In the present invention, at least (i) in the step of causing the transparent substrate thus processed and the substrate having the solid-state image pickup devices to be arranged so that the individual transparent substrates face the solid-state image pickup devices, respectively, or (ii) in the step of causing the first substrate on which the sealing agent is applied and the second substrate holding the individual transparent substrates to face each other so that the individual transparent substrates face the solid-state image pickup devices, respectively, a peripheral part of the transparent substrate or the substrate having the solid-state image pickup devices may be held.

According to the method above, a peripheral part of the transparent substrate or the substrate having the solid-state image pickup devices is directly held. That is, the transparent substrate or the substrate having the solid-state image pickup devices is not indirectly held. This leads to reduction in a manufacturing time due to reduced manufacturing steps, reduction of material cost, and the like, in contrast with a method by which the transparent substrate or the substrate having the solid-state image pickup devices is directly held.

Methods for holding the transparent substrate or the substrate having the solid-state image pickup devices include, for example, a method by which each substrate is seized (pinched), a method by which a ring-like member or a claw sticks to each substrate, and the like.

In the present invention, at least (i) in the step of causing the transparent substrate thus processed and the substrate having the solid-state image pickup devices to be arranged so that the individual transparent substrates face the solid-state image pickup devices, respectively, or (ii) in the step of causing the first substrate on which the sealing agent is applied and the second substrate holding the individual transparent substrates to face each other so that the individual transparent substrates face the solid-state image pickup devices, respectively, the transparent substrate or the substrate having the solid-state image pickup devices may be held by adhesion.

According to the method, the transparent substrate or the substrate having the solid-state image pickup devices is held by adhesion. That is, the transparent substrate or the substrate having the solid-state image pickup devices is held indirectly. Accordingly, the transparent substrate and the substrate having the solid-state image pickup devices can be set in the same size. This makes it possible to perform a step using a general-purpose chuck or conveyer. Accordingly, steps can be carried out on one manufacturing line.

In the present invention, the support preferably holds the transparent substrate so that deflection of the transparent substrate is reduced.

According to the method, the support supports the transparent substrate so as to reduce a deflection thereof more than a case where the support is not used. This maintains parallelism between the substrate having the solid-state image pickup devices and the transparent substrate. As a result, alignment can be carried out with a high degree of precision when the substrate having the solid-state image pickup devices and the transparent substrate are opposed to each other. Specifically, when the substrate having the solid-state image pickup devices and the transparent substrate are opposed to each other, a space therebetween can be adjusted to a set value with a high degree of precision.

In the present invention, the method for manufacturing a solid-state image pickup device module may further includes the step of: forming on the transparent substrate an IR cut coating that has the same size as that of the transparent substrate, before the step of processing a transparent substrate or before the step of cutting the transparent substrate.

According to the method, the IR cut coating is formed on the transparent substrate before the step of processing a transparent substrate or the step of cutting a transparent substrate. By cutting the transparent substrate on which the IR cut coating has been formed, formed is a transparent substrate for a chip on which the IR cut coating has been formed. This makes it possible to form the IR cut coating easier than a method by which the IR cut coating is formed on each transparent substrate for a chip. That is, according to the method, the IR cut coating is formed on the transparent substrate at a time. As a result, a processing speed and a yield can be improved.

Methods for forming an IR cut coating on the transparent substrate include, for example, vapor deposition, sputtering, and the like.

As described above, according to the present invention, the transparent substrate and the substrate having the solid-state image pickup devices are bonded to each other at a time. As a result, better manufacturing efficiency can be obtained. Also, the transparent substrate and the substrate having the solid-state image pickup devices are not cut at a time. Therefore, each substrate can be cut easily.

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1 is a flowchart illustrating a method for manufacturing a solid-state image pickup device module of the first embodiment of the present invention.

FIG. 2 is an explanatory diagram illustrating a step of processing a wafer in the method of FIG. 1.

FIG. 3 is an explanatory diagram illustrating a step of processing a transparent substrate in the method of FIG. 1.

FIG. 4 is an explanatory diagram illustrating a modularizing step in the method of FIG. 1.

FIG. 5 is a flowchart illustrating a method for manufacturing a solid-state image pickup device module in accordance with the second embodiment of the present invention.

FIG. 6 is an explanatory diagram illustrating a step of processing a wafer in the method of FIG. 5.

FIG. 7 is an explanatory diagram illustrating a modularizing step in the method of FIG. 5.

FIG. 8 is an explanatory diagram illustrating a step of processing a transparent substrate in a method for manufacturing a solid-state image pickup device module in accordance with the third embodiment of the present invention.

FIG. 9 is an explanatory diagram illustrating a modularizing step in the method for manufacturing a solid-state image pickup device module in accordance with the third embodiment of the present invention.

FIG. 10(a) is a cross-sectional view illustrating a structure in which a transparent substrate or a solid-state image pickup device is held, both of which are different from those in FIG. 9.

FIG. 10(b) is a cross-sectional view illustrating a structure in which a transparent substrate or a solid-state image pickup device is held, both of which are different from those in FIGS. 9 and 10(a).

FIG. 10(c) is a cross-sectional view illustrating a structure in which a transparent substrate or a solid-state image pickup device is held, both of which are different from those in FIGS. 9, 10(a), and 10(b).

FIG. 10(d) is a cross-sectional view illustrating a structure in which a transparent substrate or a solid-state image pickup device is held, both of which are different from those in FIGS. 9 and 10(a) to 10(c).

### EXPLANATION OF LETTERS AND NUMERALS

S1 Step of forming solid-state image pickup device etc.
S2 Backgrinding step
S3 Washing step
S4 Sealing agent application step
S5 Sealing agent exposure step
S6 Film peeling/exposure step
S11 Shape adjustment cutting step
S12 End surface planarizing step
S13 IR cut coating step
S14 Support attaching step
S15 Transparent substrate cutting step
S16 Transparent substrate washing step
S17 Supporting tape attaching step
S21 wafer and transparent substrate combining step
S22-1 Supporting tape detaching step
S22-2 Transparent substrate and adhesive detaching step
S23 Sealing agent curing step
S24 Dicing seat attaching step
S25 Wafer dicing step
S26 Die bonding step
S27 Wire bonding step
S28 Module assembling step
S33 Dicing step
S34 Chip sorting step
S35 Chip washing step
10 Wafer (substrate having solid-state image pickup devices)
11 Solid-state image pickup device
12 Terminal
13 Sealing agent
20 Transparent substrate
21 IR cut coating
22 Support
23 Cutting device
24 Supporting tape
25 Individual transparent substrate
26 Supporting ring
27 Adhesive
31 Dicing seat
32 Dicer
33 Printed circuit board
34 Wire
35 Module housing
36 Lens
37 Lens package
38 Solid-state image pickup device chip
51 Dummy substrate
70 Holder
70a Claw-like member or ring

### BEST MODE FOR CARRYING OUT THE INVENTION

### First Embodiment

(Step of Processing a Substrate Having Solid-State Image Pickup Devices)

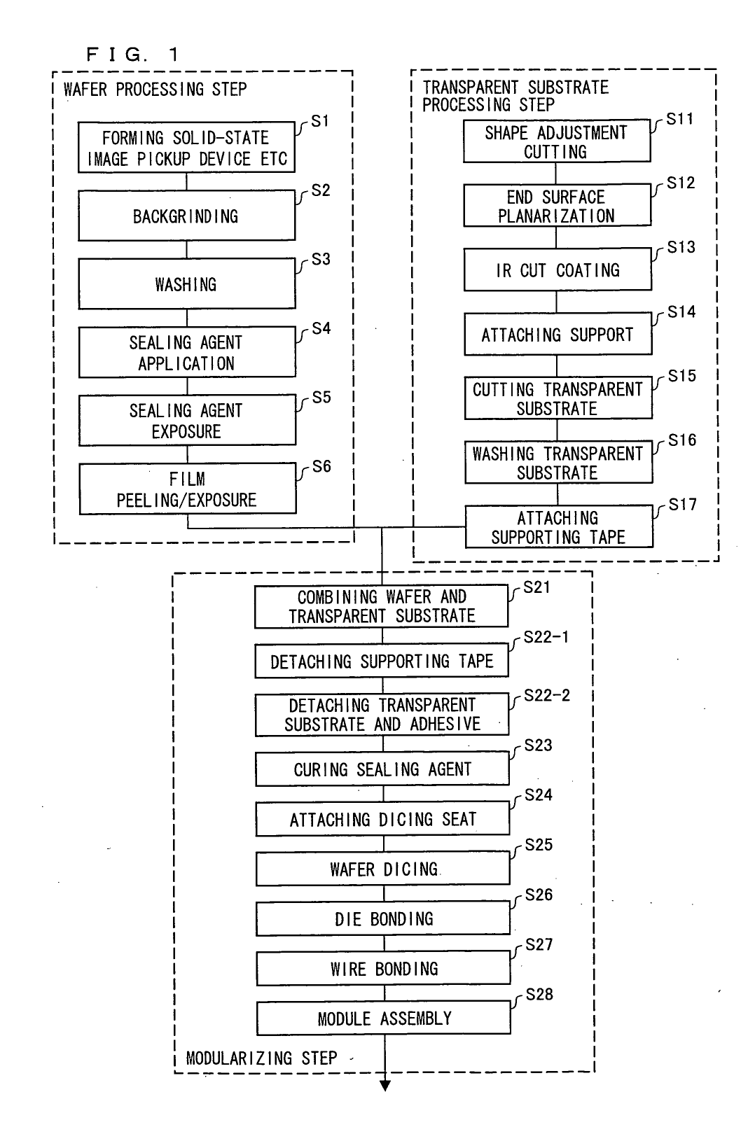

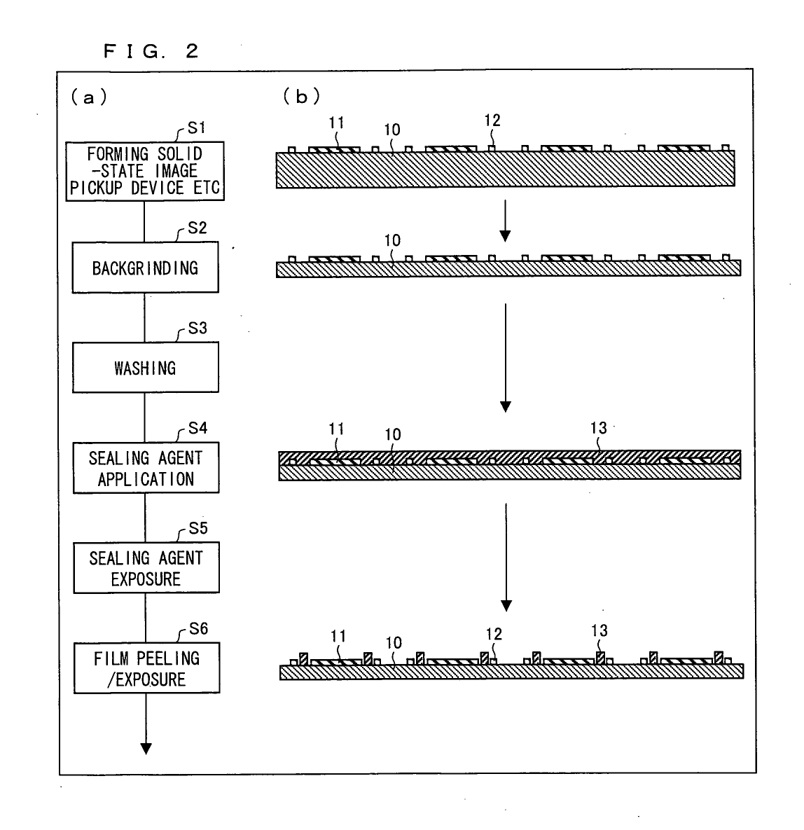

FIG. 1 is a flowchart illustrating a method for manufacturing a solid-state image pickup device module of the first embodiment in accordance with the present invention. The following description initially deals with a step of processing a substrate having solid-state image pickup devices, which processing step is illustrated in FIG. 1. In the present embodiment, a wafer processing step is described adopting a wafer as one example of a substrate having solid-state image pickup devices. Therefore, a wafer processing step in a dotted box of FIG. 1 corresponds to a step of processing a substrate having solid-state image pickup devices. FIG. 2 is an explanatory diagram illustrating the wafer processing step in detail. (a) of FIG. 2 is a flowchart illustrating the wafer processing step in FIG. 1. (b) of FIG. 2 is a cross-sectional view illustrating wafers etc. corresponding to main steps in (a) of FIG. 2.

In a step of forming a solid-state image pickup device etc., a solid-state image pickup device 11 and a terminal 12 are formed on a wafer 10 made of, for example, silicon material (S1). The solid-state image pickup device 11, which is made based on a conventional technique, such as an image sensor which is a CCD (Charge Coupled Device), a CMOS (Complementary Metal Oxide Semiconductor), or the like. Since a conventional process can be applied to such a step, a detailed description is omitted.

Note that the solid-state image pickup device 11 does not indicate a photodiode itself. A transparent substrate (later described) is to be provided with respect to an area where a plurality of photodiodes are aligned. When the solid-state image pickup device 11 is referred to, at least an area where a plurality of photodiodes are aligned is included. It does not matter whether or not other control parts are included.

Then, backgrinding is carried out with respect to the wafer 10 so that the solid-state image pickup device module becomes thin (S2). Since an art for conventional technique is applicable to the backgrinding, no specific description is given here. The backgrinding causes the wafer 10, which has an initial thickness of about 700 μm, to become thin so as to have a thickness falling in a range of 100 to 300 μm.

A washing step (S3) is carried out so that dust generated in the backgrinding step (S2) is removed. On a surface of the wafer 10 on which the solid-state image pickup devices 11 are formed, a sealing agent 13 is applied so as to entirely cover at least areas where the solid-state image pickup devices 11 are formed (S4: sealing agent application step). The sealing agent application step is carried out by applying the sealing agent 13 or by sticking a sealing agent 13 made of sheet-like material. The sealing agent 13 can be, for example, acrylic, epoxy, polyimide photosensitive thermosetting resin or the like.

Patterning of the sealing agent 13 is carried out with respect to the wafer 10 as follows. Specifically, an exposure step (S5: sealing agent exposure step) is carried out with the use of conventional photolithography, and then a film peeling step and an exposure step are carried out (S6: film peeling/exposure step). This allows a convex sealing agent 13 to be patterned and provided around each of the solid-state image pickup devices 11. The convex sealing agent 13 is joined onto an individual transparent substrate when the individual transparent substrate is attached onto the wafer 10. More specifically, the sealing agent 13 is formed so as to be outside the solid-state image pickup device 11 and inside the terminal 12 for external connection, and the sealing agent 13 has a substantially uniform height so as to seal a part other than a labyrinthine air vent provided for preventing an inner surface of a transparent substrate 20 from becoming fogged. Thus, a step of processing a substrate having solid-state image pickup devices is completed.

(Step of Processing a Transparent Substrate)

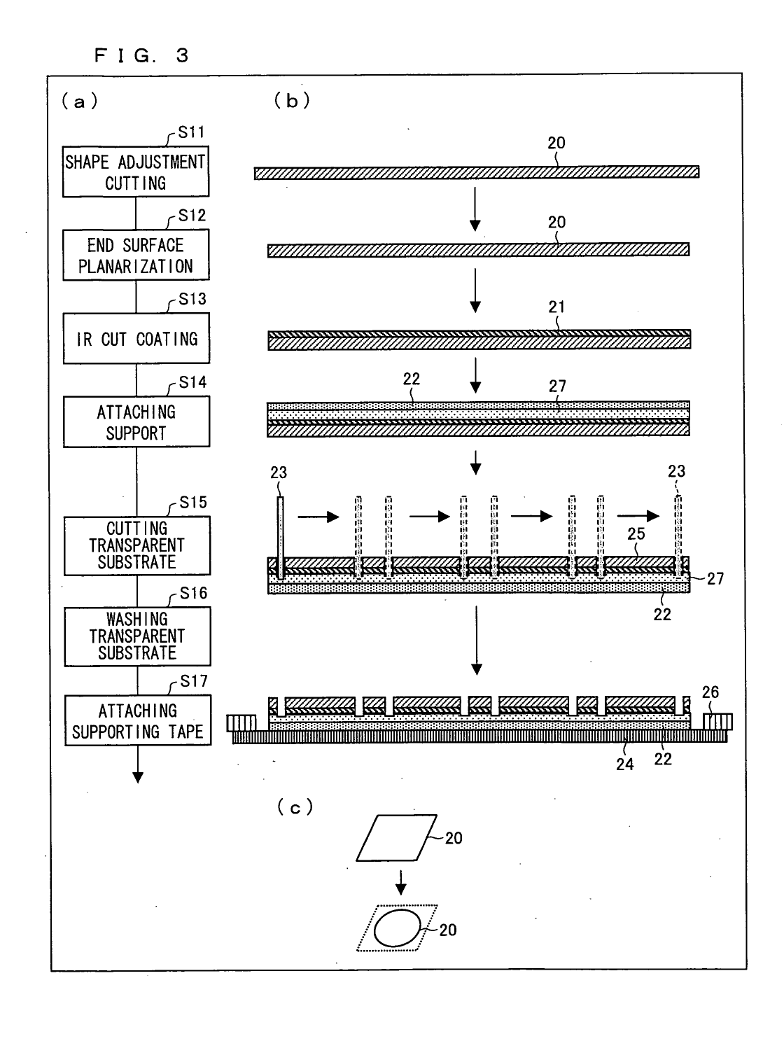

The following describes a step of processing a transparent substrate. FIG. 3 illustrates a transparent substrate processing step in detail. (a) of FIG. 3 is a flowchart illustrating the transparent substrate processing step of FIG. 1. (b) of FIG. 3 is a cross-sectional view illustrating the transparent substrate 20 etc. in main steps shown in (a) of FIG. 3.

First, a transparent substrate 20 is cut in a circular form so as to have substantially the same periphery as a wafer 10. This allows the transparent substrate 20 and the wafer 10 to be easily provided so that they face each other. (S11: shape adjustment cutting step). (c) of FIG. 3 is a perspective view illustrating the transparent substrate 20 obtained before and after the shape adjustment cutting step (S11) in (a) and (b) of FIG. 3. In (c) of FIG. 3, the part inside the continuous line indicates an actually remaining part of the transparent substrate 20, whereas the part inside the dashed line is a part to be cut off. In this step, the transparent substrate 20, having a rectangular shape, is cut so as to have a circular transparent substrate 20. It is preferable to thus cut the transparent substrate 20 into the same shape as the wafer 10 in this step because this allows the transparent substrate 20 to be processed with the use of a general-purpose chuck or a general-purpose conveyer. Examples of the transparent substrate 20 include glass, quartz, and transparent resin.

Then, a step of planarizing an end surface of the transparent substrate 20 thus cut is carried out so that an edge of the transparent substrate 20 thus cut is arranged and improved (S12: end surface planarizing step). An IR cut coating 21 for decreasing transmission rate of infrared rays to the solid-state image pickup device 111 is formed on the transparent substrate 20 (S13: IR cut coating step). The IR cut coating step can be realized with the use of a conventional technique such as a vapor deposition by sputtering. Hereinafter, a transparent substrate 20 that has been subjected to an IR cut coating step may also be referred to as the transparent substrate 20. In an IR cut coating step of the present embodiment, an IR cut coating 21 having the same shape as a transparent substrate 20 is formed on the entire surface of the transparent substrate 20 by vapor deposition.

Then, a support 22 is attached onto the IR cut coating 21 (S14: support attaching step). This is realized with the use of an adhesive 27 formed on the support 22. This causes the IR cut coating 21 to be sandwiched between the support 22 (adhesive 27) and the transparent substrate 20. The support 22 and the adhesive 27 are provided in order to temporarily fix and hold the individual transparent substrate 20 and IR cut coating 21 that have been subjected to the cutting by a cutting device 23.

A board having the same shape as that of the wafer 10 and a thickness approximately in a range of 300 μm to 1000 μm can be used as a support 22, on which the adhesive 27 is provided. An adhesive can be used as the adhesive 27, which adhesive contains a foaming material causing a generation of bubbles in response to irradiation of UV light (ultraviolet light), so that adhesion of the adhesive is decreased. In a case where (i) a transparent material such as glass, quartz, transparent resin, or their combined material is used as the board and (ii) a transparent adhesive is used as the adhesive 27, an alignment mark on the wafer 10 can be confirmed through the transparent substrate 20. This is suitable for an easy alignment. Note that the alignment here indicates a horizontal (planar directions, i.e., X and Y directions) alignment.

Although described above, an adhesive can be used as the adhesive 27, which adhesive contains a foaming material causing a generation of bubbles in response to irradiation of UV light (ultraviolet light), so that adhesion of the adhesive is decreased. However, an adhesive which can be used as the adhesive 27 is not limited to such an adhesive, provided that an adhesion of the adhesive is decreased in response to externally applied force. Other materials of the adhesive 27 include (i) a material containing a foaming agent that generates bubbles in response to an application of heat, so that adhesion of the material is decreased and (ii) a material that becomes hardened in response to application of heat or irradiation of UV light, so that adhesion of the material is decreased. For example, REVALPHA® of Nitto Denko Corporation can be used as the thermosetting adhesive that becomes hardened in response to application of heat so that adhesion of the adhesive is decreased. In a case where the thermosetting adhesive is used so as to decrease the adhesion of the adhesive, the following UV irradiation step needs to be replaced with a heating step. The following describes an example in which adhesion is decreased in response to irradiation of UV light.

Then, the transparent substrate 20 and the IR cut coating 21 are cut by the cutting device 23 so as to have a predetermined shape. This causes individual transparent substrates 25 to be provided (S15: transparent substrate cutting step). Used as the cutting device 23 is a dicer, a slicer, a wire saw, laser, or the like. A depth to be cut by the cutting device 23 is set to a depth so that the transparent substrate is completely cut off and so that the adhesive 27 is not completely cut off. This allows the board, of which the support 22 is made, to be reusable without being cut off. Such a predetermined shape, which the transparent substrate 20 and the IR cut coating 21 have after being cut off, is substantially the same as the periphery of the sealing agent 13 to which the patterning has been carried out.

According to the present embodiment, as described above, the IR cut coating, having the same shape as the transparent substrate 20, is formed on the transparent substrate 20, in the IR cut coating step (S13). Accordingly, in the transparent substrate cutting step (S15), it is possible to form the individual transparent substrates 25 on which the IR cut coating 21 has been formed, by cutting the transparent substrate 20 on which the IR cut coating 21 has been formed. Therefore, it is possible to form the individual transparent substrates 25 on which the IR cut coating 21 has been formed more easily than a case where an IR cut coating 21 is formed on each of individual transparent substrates 25. Moreover, it is possible to realize an improvement in processing speed and yield because the IR cut coating 21 is formed on the transparent substrate 20 in a lump.

Then, the transparent substrate 20 is washed (S16: transparent substrate washing step) so that cullet and particles, generated in the transparent substrate cutting step (S15), are removed. A supporting tape 24 is attached to a surface of the support 22 opposite to a surface on which the IR cut coating 21 has been formed (S17: supporting tape attaching step). Thus, a transparent substrate processing step is completed. A supporting ring 26, which serves as a metal frame, is provided on the same surface of the supporting tape 24, on which surface the transparent substrate 20 is attached. The transparent substrate 20 thus processed is provided in the supporting ring 26.

Since an attaching step, which is to be carried out later, is carried out in an atmosphere whose temperature falls approximately in a range of 60° C. to 120° C., the material of the supporting tape 24 is selected so as to withstand temperatures of up to 60° C. to 120° C. Examples of the material include PE (Polyethylene), PP (Polypropylene), and PET (Polyethylene terephthalate). PET is the most suitable material in view of temperature and external factors. The supporting tape 24 is fixed inside the supporting ring 26, which serves as a metal frame. The surface of the supporting tape 24 can be made of material similar to the one described above for combining the support 22 with the transparent substrate 20. The following description deals with an example in which a material whose adhesion is decreased in response to irradiation of UV is used.

(Step of Combining a Substrate Having Solid-State Image Pickup Devices with a Transparent Substrate)

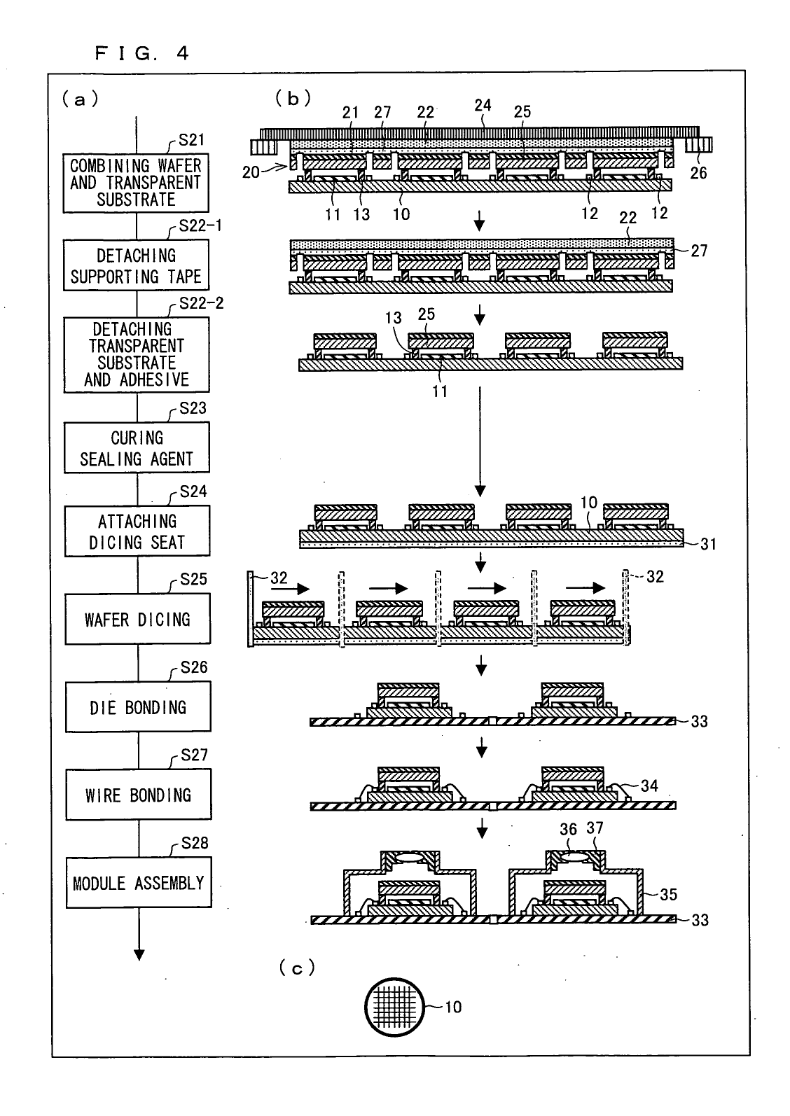

The following describes a modularizing step, which includes a step (wafer and transparent substrate combining step S21) of combining the wafer 10 (a substrate having solid-state image pickup devices) with the transparent substrate 20. FIG. 4 is an explanatory diagram illustrating the modularizing step in detail. (a) of FIG. 4 is a flowchart of the modularizing step illustrated in FIG. 1. (b) of FIG. 4 is a cross-sectional view illustrating main steps in (a) of FIG. 4.

Firstly, the wafer 10 and the transparent substrate 20 are aligned so as to face each other. On this occasion, an alignment is carried out so that individual transparent substrates 25 are appropriately aligned with respect to a patterned sealing agent 13, respectively (S21: wafer and transparent substrate combining step), while (i) a surface of the transparent substrate 20 on which the IR cut coating 21 has been formed and (ii) a surface of the wafer 10 on which the solid state image pickup devices have been formed face each other. In this step, it is preferable to carry out the alignment with high precision. Accordingly, the alignment is carried out, for example, with the use of a microscope so that a marking on the transparent substrate 20 and a marking on the wafer 10 are aligned. This allows the wafer 10 and the transparent substrate 20 to be combined with each other with high precision. Under conditions (atmospheric conditions), for this step, in which (i) substantially a vacuum state in which an atmospheric pressure falls in a range of 100 Pa to 300 Pa and (ii) a temperature in a range of 60° C. to 120° C., a pressure in a range of 0.05 Mpa to 0.5 Mpa is applied, for 1 second to 600 seconds, to the wafer 10 and the transparent substrate 20 so that the wafer 10 and the transparent substrate 20 are combined with each other (This is included in S21).

In the wafer and transparent substrate combining step, the supporting tape 24 holds the supporting ring 26 and the support 22. This causes a part of the supporting tape 24 between the supporting ring 26 and the support 22 is stretched, thereby giving a rise to a deflection. Since this causes the transparent substrate 20 to have a deflection, the transparent substrate 20 cannot be held parallel to the wafer 10. Therefore, the transparent substrate 20 is preferably held so as to have a reduced deflection. In particular, the transparent substrate 20 is vertically held by the support 22 when the wafer 10 (a substrate having solid-state image pickup devices) and the transparent substrate 20 face each other in S21. On this occasion, the support 22 preferably holds the transparent substrate 20 so that the transparent substrate 20 does not have a deflection (i.e., so that a deflection is reduced). Note that the “deflection” is tolerated if it is to an extent that the transparent substrate 20 does not have a substantial deflection. For example, it is preferable that a deflection is 0.1 mm or less all over the area on surface of the transparent substrate 20 which surface faces the wafer 10. When the transparent substrate 20 is thus held so as not to have a substantial deflection, the transparent substrate 20 is kept parallel to the wafer 10. As a result, the transparent substrate 20 (the transparent substrate 20 and the IR cut coating 21) can be held stably by the support 22. Furthermore, when the transparent substrate 20 is kept parallel to the wafer 10, it is possible to carry out an alignment, with high precision, between the transparent substrate 20 and the wafer 10 all over the wafer 10.

Then, irradiation of UV is carried out on the adhesive 27 so that the adhesion of the adhesive 27 is decreased. The supporting tape 24 is detached from the adhesive 27, together with the supporting ring 26 (S22-1: supporting tape detaching step). Furthermore, the adhesive 27 is detached from the IR cut coating 21 on the transparent substrate 20, together with the support 22 (S22-2: transparent substrate and adhesive detaching step).

The sealing agent 13 is then heated and maintained at a temperature in a range of approximately 120° C. to 170° C. for 40 minutes to 80 minutes so as to be cured (S23: sealing agent curing step). This causes the solid-state image pickup device 11 to be surrounded, except the air vent, by the sealing agent 13 and the individual transparent substrates 25 are provided on the surface opposite to the solid-state image pickup device 11.

A dicing seat 31 is attached onto a back surface of the wafer 10 (i.e., a surface opposite to the surface on which the solid-state image pickup devices etc. are formed). The wafer 10 is diced with the use of a cutting device 32 along a chip detaching area on the wafer 10 so that the wafer 10 is divided into chips (S25: wafer dicing step). A dicer is used as the cutting device 32. (c) of FIG. 4 is a top view schematically illustrating a diced wafer 10.

Each of the chips is fixed, by bonding, to a printed circuit board 33 which is provided in advance with terminals to be connected to wiring and the terminal 12 on a chip (S26: die bonding step). Then, a terminal on the printed circuit board 33 and the terminal 12 on a chip are connected with a wire 34 (S27: wire bonding step) so that the chip and the printed circuit board 33 are electrically connected and operate properly.

A module housing 35 is attached outside the terminals on the printed circuit board 33. The module housing 35 has a function of supporting a lens package 37, which holds a lens 36. This causes the lens 36 and the surface of the transparent substrate 20 on which the IR cut coating 21 is formed to face and be away from each other by a predetermined distance (S28: module assembling step). The printed circuit board 33 is divided into solid-state image pickup device modules, thereby obtaining individual solid-state image pickup device modules.

(Functions/Effects)

In the present embodiment, as described above, a transparent substrate 20 is divided into individual transparent substrates (individual transparent substrates 25) before combining the transparent substrate 20 with a wafer 10. This makes the cutting easy because the transparent substrate 20 and the wafer 10 are not cut at the same time. By the wafer, the transparent substrate 20 is combined with the wafer 10 in a lump at a time. Therefore, fine manufacturing efficiency can be obtained.

In addition, a material, whose adhesion is decreased in response to irradiation of UV or when a temperature exceeds a predetermined value, is used as an adhesive applied to a member that is detached after being temporarily attached to the transparent substrate 20 or the wafer 10, such an adhesive attaching the transparent substrate 20 with the support 22, for example. Since this allows an easy detachment of the member in a series of manufacturing steps, defects due to an attachment are less likely to occur.

In the present embodiment, a transparent substrate 20 is adhered and held by a supporting tape 24. This allows the transparent substrate 20 and a wafer 10 to be set so that they have the same size. The supporting tape 24 preferably holds by adhesion either the transparent substrate 20 or the wafer 10 whose surface facing to the other member faces downward.

### Second Embodiment

The following describes the second embodiment of the present invention. In the first embodiment, a wafer is cut after being combined with a transparent substrate, whereas, in the second embodiment, the wafer is cut in a wafer processing step. This is the main difference between the first and second embodiments.

(Step of Processing a Substrate Having Solid-State Image Pickup Devices)

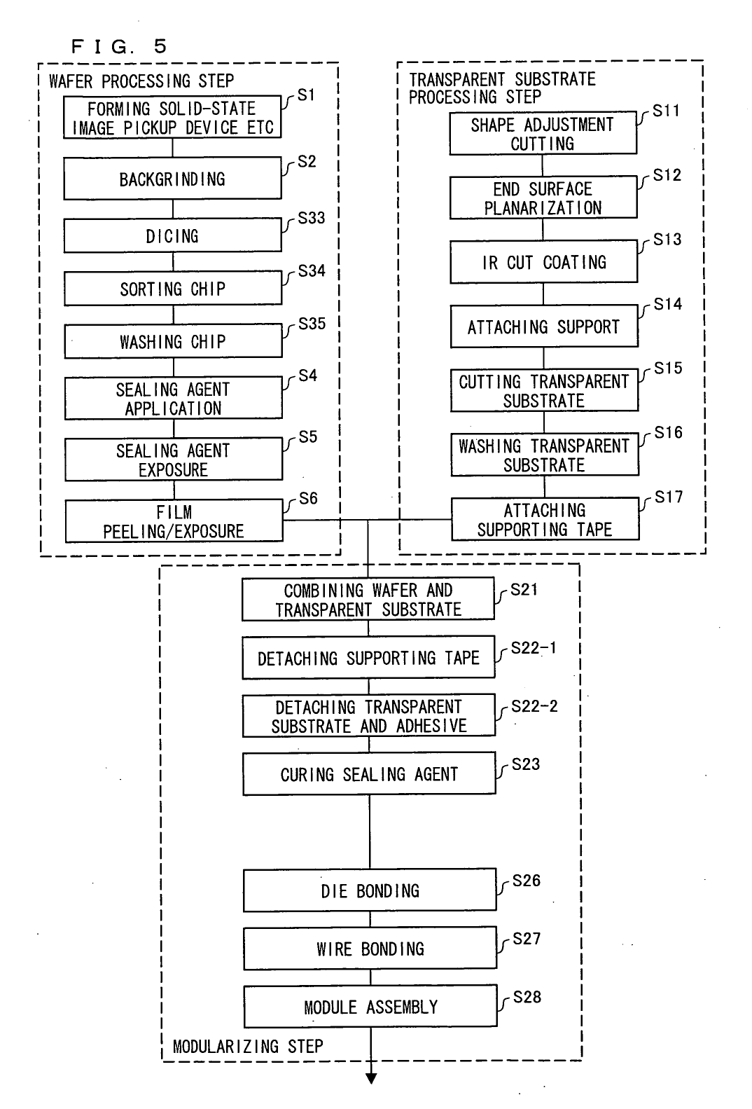

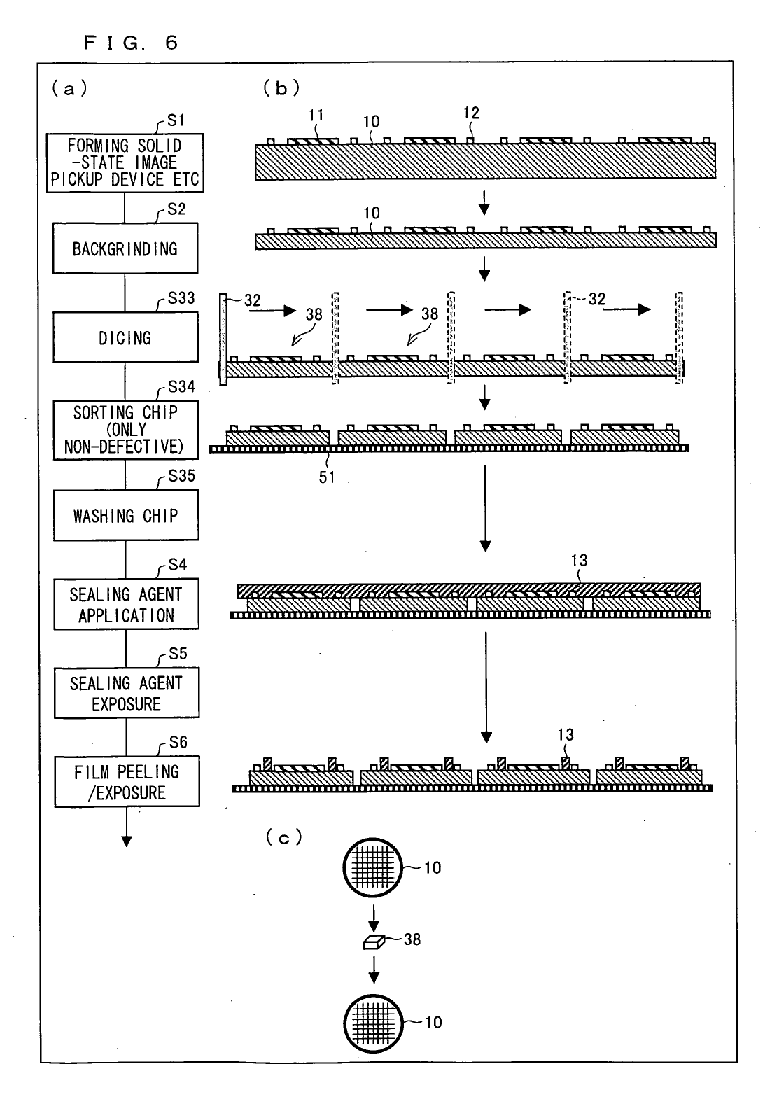

FIG. 5 is a flowchart illustrating a method for manufacturing a solid-state image pickup device module of the second embodiment. The following firstly describes a step of processing a substrate having solid-state image pickup devices, which step is illustrated in FIG. 5. In the second embodiment as well as the first embodiment, a wafer processing step is described, taking a wafer as a concrete example of a substrate having solid-state image pickup devices. Therefore, the wafer processing step illustrated in a dotted box in FIG. 5 corresponds to a step of processing a substrate having solid-state image pickup devices. FIG. 6 is an explanatory diagram illustrating the wafer processing step in detail. (a) of FIG. 6 is a flowchart illustrating the wafer processing step illustrated in FIG. 5. (b) of FIG. 6 is a cross-sectional view illustrating a wafer etc. in main steps in (a) of FIG. 6.

In a step of forming a solid-state image pickup device etc., a solid-state image pickup device 11 and a terminal 12 are formed on a wafer 10 made of, for example, silicon material (S1). The solid-state image pickup device 11, which is made based on a conventional technique, such as an image sensor which is a CCD (Charge Coupled Device), a CMOS (Complementary Metal Oxide Semiconductor), or the like. Since a conventional process can be applied to such a step, a detailed description is omitted.

Then, backgrinding is carried out with respect to the wafer 10 so that the solid-state image pickup device module becomes thin (S2). Since an art for conventional technique is applicable to the backgrinding, no specific description is given here. The backgrinding causes the wafer 10, which has an initial thickness of about 700 μm, to become thin so as to have a thickness falling in a range of 100 to 300 μm.

The wafer 10 that has been subjected to the backgrinding is diced along a chip detachment area thereon so as to be divided into solid-state image pickup device chips 38 (S33: dicing step). A dicer is used as the cutting device 32. The chips are washed (not illustrated) so that dust particles etc. generated due to the dicing is removed.

The solid-state image pickup device chips 38 thus diced are inspected so that only non-defective solid-state image pickup device chips 38 are picked up. Only the non-defective solid-state image pickup device chips 38 are sorted and aligned again in the shape of a wafer (S34: chip sorting step). In the chip sorting step S34, only the solid-state image pickup device chips 38 that have been determined to be non-defective by an inspection are sorted with a sorter and aligned on a dummy substrate 51 in the shape of a wafer.

(c) of FIG. 6 schematically illustrates how the processing is carried out from the dicing step to the chip sorting step. As illustrated in (c) of FIG. 6, the wafer 10 is cut and divided into the solid-state image pickup device chips 38. Only non-defective solid-state image pickup device chips 38 are aligned again in the shape of a wafer.

By thus picking up and sorting only non-defective solid-state image pickup device chips 38, the solid-state image pickup device chip 38 which has been combined with a transparent substrate 20 basically has no defect due to a defect of a step occurred before the wafer and transparent substrate combining step. This makes it possible to improve the throughput of non-defective solid-state image pickup device chips 38 obtained after the wafer and transparent substrate combining step (S21).

Even if a step of picking up only non-defective solid-state image pickup device chips 38 is omitted, there is still an advantage derived from cutting the wafer 10 before the wafer and transparent substrate combining step (S21). Note however that there is no advantage derived from picking up only the non-defective solid-state image pickup device chips 38. In the present description, a step of aligning and holding solid-state image pickup device chips 38 is referred to as a “step of aligning and holding solid-state image pickup device chips,” regardless of whether or not non-defective solid-state image pickup device chips 38 are picked up. Although the description deals with a case where solid-state image pickup device chips 38 are aligned in the shape of a wafer, the shape is not limited to a disk-like shape. Alternatively, solid-state image pickup device chips 38 can be aligned in any shape, provided that a wafer 10 (substrate having solid-state image pickup devices) and a transparent substrate 20 can easily face each other. For example, the shape may be a rectangular shape or other polygonal shape.

After removing foreign bodies from the wafer 10 in the chip washing step (S35), the sealing agent 13 is applied on the wafer 10 (S4: sealing agent application step). In the sealing agent application step, the sealing agent 13 is applied, on the surface of the wafer 10 on which the solid-state image pickup devices are formed, so as to entirely cover at least area where the solid-state image pickup devices 11 are formed. In the sealing agent application step, the sealing agent 13 is applied to the wafer 10 or a sealing agent 13 made of sheet-like material is attached to the wafer 10. For example, an acrylic photosensitive thermosetting resin, an epoxy photosensitive thermosetting resin, or a polyimide photosensitive thermosetting resin can be used as the sealing agent 13.

Patterning of the sealing agent 13 is carried out with respect to the wafer 10 as follows. Specifically, an exposure step (S5: sealing agent exposure step) is carried out with the use of conventional photolithography, and then a film peeling step and an exposure step are carried out (S6: film peeling/exposure step). This allows a convex sealing agent 13 to be patterned and provided around each of the solid-state image pickup devices 11. The convex sealing agent 13 is joined onto an individual transparent substrate when the individual transparent substrate is attached onto the wafer 10. More specifically, the sealing agent 13 is formed so as to be outside the solid-state image pickup device 11 and inside the terminal 12 for external connection, and the sealing agent 13 has a substantially uniform height so as to seal a part other than a labyrinthine air vent provided for preventing an inner surface of a transparent substrate 20 from becoming fogged. Thus, a step of processing a substrate having solid-state image pickup devices is completed.

(Step of Processing a Transparent Substrate)

A step of processing a transparent substrate is the same as that described in the first embodiment (see FIG. 3). Therefore a description is omitted.

(Step of Combining a Substrate Having Solid-State Image Pickup Devices with a Transparent Substrate)

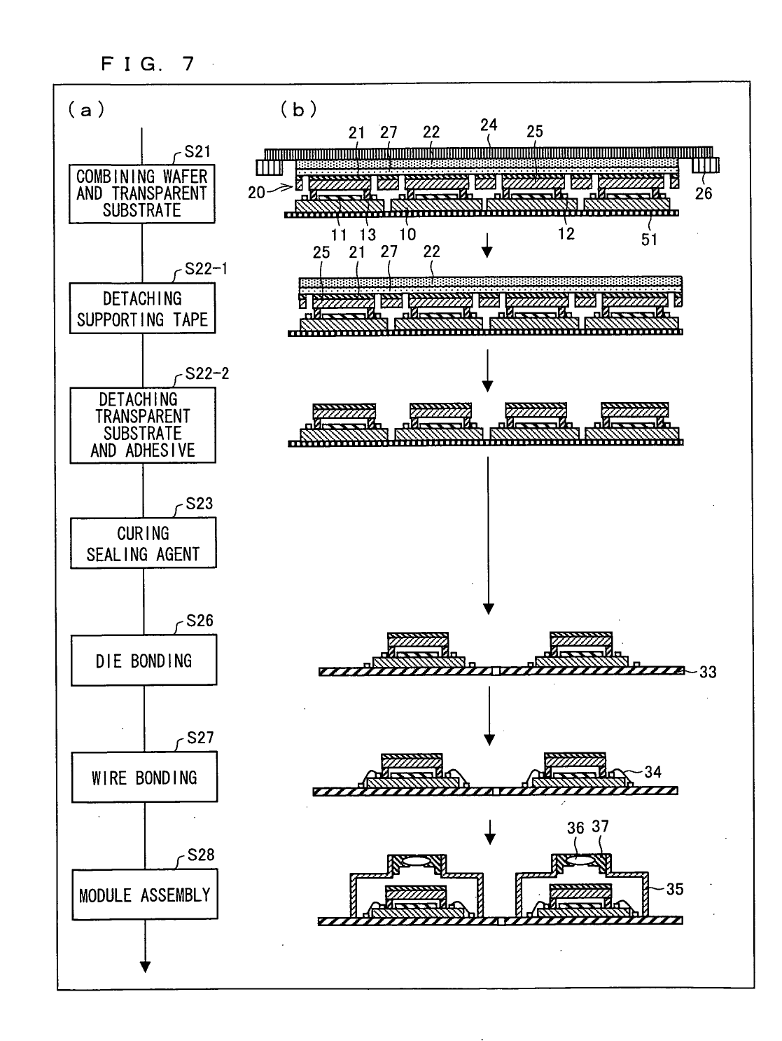

The following describes a modularizing step, which includes a step (wafer and transparent substrate combining step) of combining the wafer 10 (a substrate having solid-state image pickup devices) with the transparent substrate 20. FIG. 7 is an explanatory diagram illustrating the modularizing step in detail. (a) of FIG. 7 is a flowchart of the modularizing step illustrated in FIG. 5. (b) of FIG. 7 is a cross-sectional view illustrating the wafer 10, the transparent substrate 20, etc. in (a) of FIG. 7.

Firstly, the wafer 10 and the transparent substrate 20 are aligned so as to face each other. On this occasion, an alignment is carried out so that individual transparent substrates 25 are appropriately aligned with respect to a patterned sealing agent 13, respectively (S21: wafer and transparent substrate combining step), while (i) a surface of the transparent substrate 20 on which the IR cut coating 21 has been formed and (ii) a surface of the wafer 10 on which the solid state image pickup devices have been formed face each other. In this step, it is preferable to carry out the alignment with high precision. Accordingly, the alignment is carried out, for example, with the use of a microscope so that a marking on the transparent substrate 20 and a marking on the wafer 10 are aligned. This allows the wafer 10 and the transparent substrate 20 to be combined with each other with high precision. Under conditions (atmospheric conditions), for this step, in which (i) substantially a vacuum state in which an atmospheric pressure falls in a range of 100 Pa to 300 Pa and (ii) a temperature in a range of 60° C. to 120° C., a pressure in a range of 0.05 Mpa to 0.5 Mpa is applied, for 1 second to 600 seconds, to the wafer 10 and the transparent substrate 20 so that the wafer 10 and the transparent substrate 20 are combined with each other (This is included in S21).

Then, irradiation of UV is carried out on the adhesive 27 so that the adhesion of the adhesive 27 is decreased. The supporting tape 24 is detached from the adhesive 27, together with the supporting ring 26 (S22-1: supporting tape detaching step). Furthermore, the adhesive 27 is detached from the IR cut coating 21 on the transparent substrate 20, together with the support 22 (S22-2: transparent substrate and adhesive detaching step).

The sealing agent 13 is then heated and maintained at a temperature in a range of approximately 120° C. to 170° C. for 40 minutes to 80 minutes so as to be cured (S23: sealing agent curing step). This causes the solid-state image pickup device 11 to be surrounded, except the air vent, by the sealing agent 13 and the individual transparent substrates 25 are provided on the surface opposite to the solid-state image pickup device 11. Then, the dummy substrate 51 is removed from the wafer 10, thereby realizing a state in which chips are provided. The state corresponds to a state in which the printed circuit board 33 is removed from the cross sectional view corresponding to S26 in FIG. 7 (i.e., the part above the printed circuit board 33).

Each of the chips is fixed, by bonding, to a printed circuit board 33 which is provided in advance with terminals to be connected to wiring and the terminal 12 on a chip (S26: die bonding step). Then, a terminal on the printed circuit board 33 and the terminal 12 on a chip are connected with a wire 34 (S27: wire bonding step) so that the chip and the printed circuit board 33 are electrically connected and operate properly.

A module housing 35 is attached outside the terminals on the printed circuit board 33. The module housing 35 has a function of supporting a lens package 37, which holds a lens 36. This causes the lens 36 and the surface of the transparent substrate 20 on which the IR cut coating 21 is formed to face and be away from each other by a predetermined distance (S28: module assembling step). The printed circuit board 33 is divided into solid-state image pickup device modules, thereby obtaining individual solid-state image pickup device modules.

(Functions/Effects)

In also the present embodiment, a transparent substrate 20 is divided into individual transparent substrates (individual transparent substrates 25) before combining the transparent substrate 20 with a wafer 10. This makes the cutting easy because the transparent substrate 20 and the wafer 10 are not cut at the same time. By the wafer, the transparent substrate 20 is combined with the wafer 10 in a lump at a time. Therefore, fine manufacturing efficiency can be obtained.

In the second embodiment, it is not necessary to carry out a cutting step (for example, a wafer dicing step S25 in the first embodiment) after the wafer and transparent substrate combining step. Accordingly, dust etc. due to the cutting step do not easily enter into the solid-state image pickup device module, unless the cutting step is carried out after the wafer and transparent substrate combining step is carried out. As a result, a yield can be improved.

By aligning only non-defective solid-state image pickup device chips 38 before the wafer and transparent substrate combining step (the chip sorting step S34), the solid-state image pickup device chip 38 which has been combined with the transparent substrate 20 basically has no defect due to a defect of a step occurred before the wafer and transparent substrate combining step. This makes it possible to improve the throughput of non-defective solid-state image pickup device chips 38 obtained after the wafer and transparent substrate combining step (S21).

### Third Embodiment

In the first and second embodiments, a supporting tape 24 is used to temporarily hold a transparent substrate 20. However, the supporting tape 24 is not necessarily provided when, for example, the strength of a support 22 is sufficient.

In view of this, the third embodiment deals with a method for temporarily holding a transparent substrate 20 without using a supporting tape 24. According to the third embodiment, no supporting tape 24 is used. Therefore, it is possible to reduce the number of steps which are necessary in the first and second embodiments. As a result, manufacturing cost can be reduced.

The third embodiment deals with a case, as an example in which no supporting tape 24 is used, where a support 22 is held instead of the supporting tape 24 when the supporting tape 24 has an enough strength.

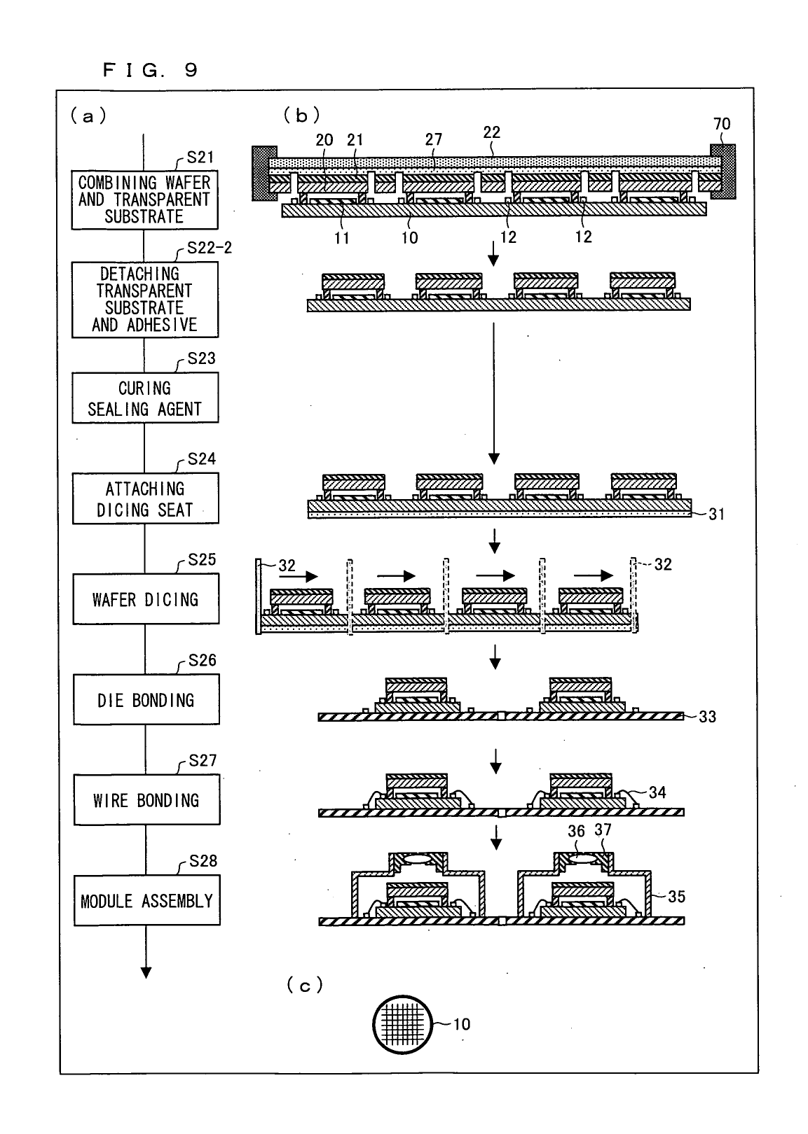

FIG. 9 is an explanatory diagram illustrating a modularizing step in accordance with the third embodiment. (a) of FIG. 9 is a flowchart illustrating the modularizing step in accordance with the third embodiment. (b) of FIG. 9 is a cross-sectional view illustrating the wafer etc. in main steps in (a) of FIG. 9. (c) of FIG. 9 is a top view schematically illustrating a top surface of the wafer when the wafer is diced. Except for a characteristic part, the third embodiment has the same arrangement as that of the first embodiment. Therefore, except for the characteristic part, members having the same functions as those of members of the first embodiment are given the same symbols, and descriptions for the members are omitted.

As illustrated in the cross-sectional view in (b) of FIG. 9 corresponding to S21 in (a) of FIG. 9, in the present embodiment, a holder 70 holds a peripheral part of the transparent substrate 20 in a wafer and transparent substrate combining step. The holder 70 may be arranged so as to hold at several positions the entire transparent substrate 20 together with the IR cut coating 21 etc. on the transparent substrate 20. Alternatively, the holder 70 may be arranged so as to hold only the support 22.

When the transparent substrate 20 is held by the holder 70, the transparent substrate 20 may have a deflection (warpage). In view of this, the third embodiment is arranged so that the support 22 reduces the deflection. That is, board constituting the support 22 is made of a material having a sufficient strength to reduce a deflection (warpage) which is caused when the holder 70 holds the transparent substrate 20. This makes it possible to keep the transparent substrate 20 parallel to the wafer 10 more surely than a case where the supporting tape 24 is used as in the first and second embodiments.

In the wafer and transparent substrate combining step (S21), the board is held at both ends thereof by the holder 70, and then the alignment between the wafer 10 and the transparent substrate 20 is carried out.

According to the step, the transparent substrate 20 is held without using the supporting tape 24. This makes it possible to address problems caused by carrying out the step of attaching the supporting tape 24. That is, it is possible to avoid a decrease in yield due to an increase in the number of steps requiring alignment, an increase in takt time, an increase in material cost, and the like.

A material is suitably used as the board which has a sufficient strength to reduce a deflection of the transparent substrate 20. In addition, it is preferable to use a transparent material (for example, glass and quartz) as the board because an alignment between the transparent substrate 20 and the wafer 10 can be easily adjusted by matching alignment marks with the use of a camera.

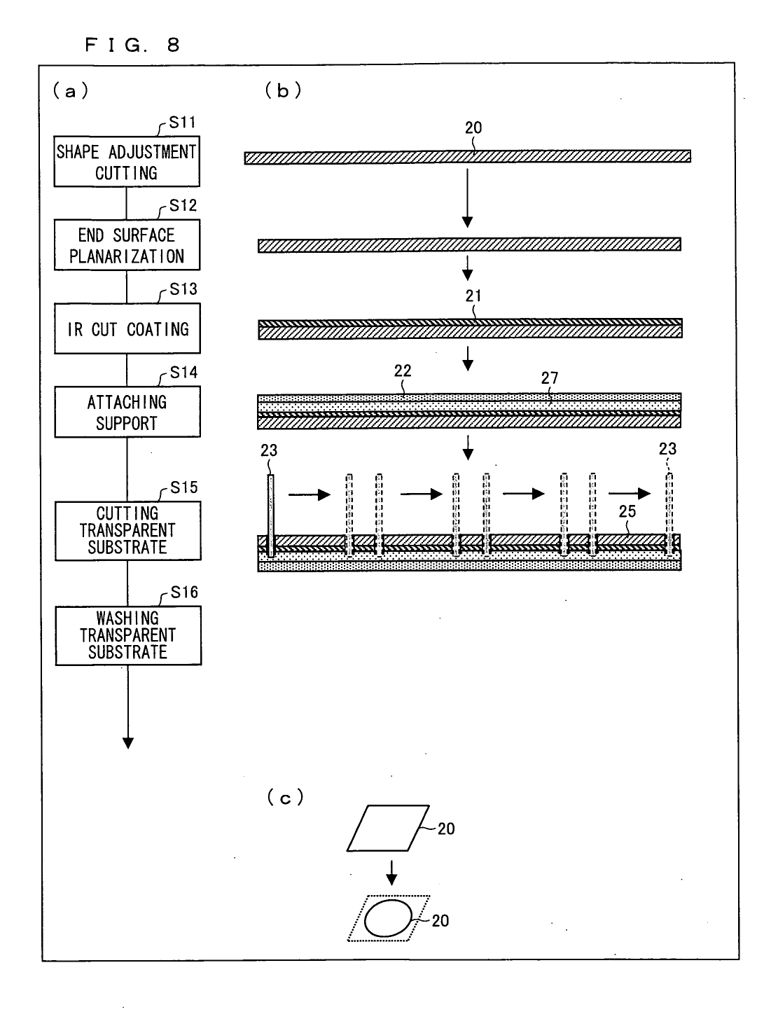

FIG. 8 is an explanatory diagram illustrating a transparent substrate processing step of the third embodiment. (a) of FIG. 8 is a flowchart illustrating the transparent substrate processing step of the third embodiment. (b) of FIG. 8 is a cross-sectional view illustrating the transparent substrate etc. in the main steps in (a) of FIG. 8. (c) of FIG. 8 is a perspective view schematically illustrating the transparent substrate 20 obtained before and after a shape adjustment cutting step (S11). When compared (a) and (b) of FIG. 8 with (a) and (b) of FIG. 3, a difference lies in that a supporting tape attaching step (S17) is provided in (a) and (b) of FIG. 3 whereas no such a step is provided in (a) and (b) of FIG. 8. In (c) of FIG. 8, the part inside the continuous line indicates an actually remaining part of the transparent substrate 20, whereas the part inside the dashed line is a part to be cut off.

As to the wafer and transparent substrate combining step (S21), a difference resides in that the supporting ring 26 is held, which is provided on the outer periphery of the supporting tape 24, in (b) of FIG. 4, whereas the support 22 itself is held in (b) of FIG. 9. Methods for holding the support 22 include, for example, a method in which portions of the support 22 to be held are seized (pinched), and a method in which portions of the support 22 to be held are absorbed by a ring-like member or a claw sticks.

In the third embodiment, the outer periphery of the transparent substrate 20 is provided outside the outer periphery of the wafer 10 so that the support 22 is held more easily. In other words, the diameter of the transparent substrate 20 is greater than that of the wafer 10. That is, the transparent substrate 20 has a larger size than the wafer 10.

As described above, it is preferable that one of parts of the outer peripheries of the transparent substrate 20 and the wafer 10 that are held at least in the wafer and transparent substrate combining step is projected. With the arrangement, the transparent substrate 20 can be easily held. This reduces a takt time and troubles of a chuck.

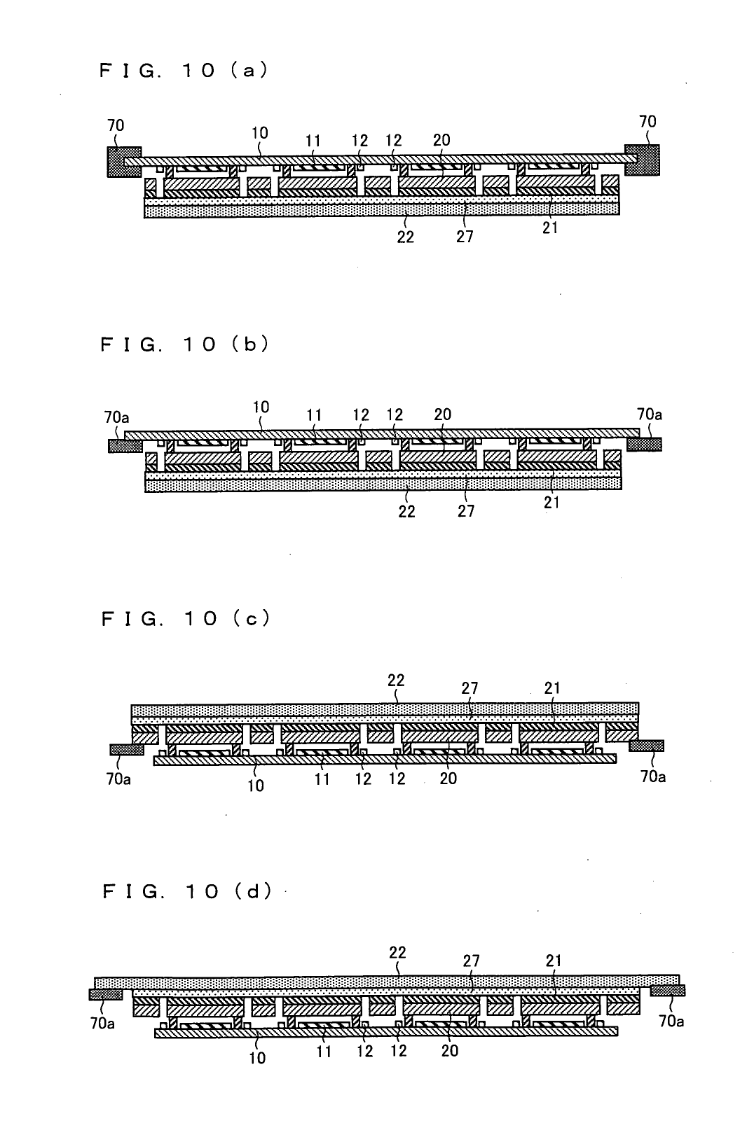

The above description deals with a case where the holder 70 holds the transparent substrate 20 (that is, the transparent substrate 20 is larger than the wafer 10). Note that the same functions and effects are brought by an arrangement in which the wafer 10 is held by the holder 70. FIG. 10(a) illustrates an arrangement in which the holder 70 holds the wafer 10. As illustrated in FIG. 10(a), the outer periphery of the wafer 10 could be held by the holder 70 when the outer periphery of the wafer 10 is greater than that of the transparent substrate 20.

As illustrated in FIG. 10(b) to (d), the wafer 10, the transparent substrate 20, or the support 22 may be placed on and held by a claw-like member or a ring member 70a, instead of the holder 70. The claw-like member holds partially (at several points) the outer periphery of the wafer 10, the transparent substrate 20, or the support 22. The ring 70a holds entirely their outer periphery.

The holder 70 illustrated in (b) of FIG. 9 and FIG. 10(a) is different from the claw-like member or the ring member 70a illustrated in FIGS. 10(b) to 10(d) in that the holder 70 holds a different part of the transparent substrate 20 or the wafer 10 than the claw-like member or the ring member 70a. More specifically, as illustrated in (b) of FIG. 9 and FIG. 10(a), the holder 70 pinches and holds the transparent substrate 20 or the wafer 10. In contrast, as illustrated in FIGS. 10(b) to 10(d), the wafer 10 (FIG. 10(b)), the transparent substrate 20 (FIG. 10(c)), or the support 22 (FIG. 10(d)) is placed on and held by the claw-like member or the ring 70a. In other words, the holder 70 pinches both sides of the transparent substrate 20 or the wafer 10 as illustrated in (b) of FIG. 9 and FIG. 10(a), whereas, as illustrated in FIGS. 10(b) to 10(d), the wafer 10, the transparent substrate 20, or the support 22 is held on the surface of the claw-like member or the ring 70a which surface faces them (FIG. 10(b)) or the wafer 10 (FIGS. 10(c) and 10(d)). In FIG. 10(d), the support 22 is slightly larger than the transparent substrate 20 and the wafer 10. In the arrangements illustrated in FIGS. 10(b) to 10(d), the wafer 10, the transparent substrate 20, or the support 22 can be held, for example, by suction. It is also possible to easily understand, from the cross-sectional views illustrating the arrangements in (b) of FIG. 9 and FIG. 10(a) and from the cross-sectional views illustrating the arrangement in FIGS. 10(b) to 10(d), (i) the arrangement in which the holder 70 holds the both sides of the wafer 10 and (ii) the arrangement in which the claw-like member or the ring 70a holds one side of the wafer 10, the transparent substrate 20, or the support 22. The holder 70, the claw-like member, or the ring 70a holds the transparent substrate 20, the wafer 10, or the support 22 at least in the step in which the transparent substrate 20 and the wafer 10 are provided so as to face each other (S21).

(Functions/Effects)

In the third embodiment, the holder 70 thus directly holds the outer periphery of the transparent substrate 20 or the wafer 10. Accordingly, the arrangement of the third embodiment is different from those described in the first and second embodiments in which the indirect holding is carried out via the supporting tape 24 and the supporting ring 26. As a result, in the third embodiment, the step of attaching a supporting tape 24 (supporting tape attaching step S17) and the supporting tape detaching step (S22) are not required, and the supporting ring 26 also are not required. This leads at least to a reduction in manufacturing time due to reduced manufacturing steps, and a reduction in material cost.

In the third embodiment, the support 22 holds the wafer 10 or the transparent substrate 20 so as not to cause a substantial deflection. This causes the substrates to be kept parallel to each other. Accordingly, it is possible to carry out an alignment, with high precision, which is carried out when the wafer 10 and the transparent substrate 20 face each other. Specifically, when the wafer 10 and the transparent substrate 20 face each other, a distance between them can be adjusted to a set value with high precision.

In the third embodiment, the transparent substrate 20 is larger than the wafer 10. However, the transparent substrate 20 may be the same size as the wafer 10. Alternatively, the transparent substrate 20 may be smaller than the wafer 10.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

The present invention realizes better manufacturing efficiency because a transparent substrate and a substrate having solid-state image pickup devices are combined with each other in a lump. Also, since the transparent substrate and the substrate having solid-state image pickup devices are not simultaneously cut off, it is possible to carry out the cutting with ease.

1. A method for manufacturing a solid-state image pickup device module, comprising the steps of:
processing a transparent substrate so that individual transparent substrates and solid-state image pickup devices face and are held, respectively, when the transparent substrate and a substrate having the solid-state image pickup devices face each other; and
causing the transparent substrate thus processed and the substrate having the solid-state image pickup devices to be arranged so that the individual transparent substrates face the solid-state image pickup devices, respectively.

2. A method for manufacturing a solid-state image pickup device module, comprising the steps of:
cutting a transparent substrate so that individual transparent substrates are prepared, which are arranged to face solid-state image pickup devices, respectively;
applying a sealing agent on a first substrate so that the sealing agent is applied around the solid-state image pickup devices which the first substrate includes;
causing said first substrate on which the sealing agent is applied and a second substrate holding the individual transparent substrates to be arranged so that the individual transparent substrates face the solid-state image pickup devices, respectively;
curing the sealing agent; and
dividing said first substrate after curing the sealing agent.

3. A method for manufacturing a solid-state image pickup device module, comprising the steps of:
dividing a substrate having a plurality of solid-state image pickup devices into solid-state image pickup device chips;
aligning and holding the solid-state image pickup device chips on a dummy substrate;
applying a sealing agent around each of the solid-state image pickup devices on the dummy substrate;
cutting a transparent substrate so that individual transparent substrates are prepared, which are arranged to face solid-state image pickup devices, respectively; and
causing (i) the dummy substrate having the solid-state image pickup device chips, which have been aligned and held and around each of which the sealing agent has been applied and (ii) a substrate holding the individual transparent substrates to face each other so that the individual transparent substrates face the solid-state image pickup devices, respectively.

4. The method for manufacturing a solid-state image pickup device module as set forth in claim 3, further comprising the step of: selecting non-defective solid-state image pickup device chips, before the step of aligning and holding the solid-state image pickup device chips.

5. The method for manufacturing a solid-state image pickup device module as set forth in claim 2, further comprising the step of:
temporarily fixing a support to the transparent substrate, before the step of cutting the transparent substrate,
wherein the support and the transparent substrate are temporarily fixed to each other via an adhesive whose adhesion is decreased in response to externally applied force.

6. The method for manufacturing a solid-state image pickup device module as set forth in claim 3 , wherein the dummy substrate and the solid-state image pickup device chips are temporarily fixed to each other via an adhesive whose adhesion is decreased in response to externally applied force.

7. The method for manufacturing a solid-state image pickup device module as set forth in claim 5,
wherein the adhesive contains (i) a foaming agent that generates bubbles in response to application of ultraviolet rays or heat or (ii) a material that becomes hardened in response to application of ultraviolet rays or heat so that adhesion of the material is decreased.

8. The method for manufacturing a solid-state image pickup device module as set forth in claim 1, wherein,
at least (i) in the step of causing the transparent substrate thus processed and the substrate having the solid-state image pickup devices to be arranged so that the individual transparent substrates face the solid-state image pickup devices, respectively, or (ii) in the step of causing the first substrate on which the sealing agent is applied and the second substrate holding the individual transparent substrates to face each other so that the individual transparent substrates face the solid-state image pickup devices, respectively,
a peripheral part of the transparent substrate or the substrate having the solid-state image pickup devices is held.

9. The method for manufacturing a solid-state image pickup device module as set forth in claim 5, wherein,
at least (i) in the step of causing the transparent substrate thus processed and the substrate having the solid-state image pickup devices to be arranged so that the individual transparent substrates face the solid-state image pickup devices, respectively, or (ii) in the step of causing the first substrate on which the sealing agent is applied and the second substrate holding the individual transparent substrates to face each other so that the individual transparent substrates face the solid-state image pickup devices, respectively,
the transparent substrate or the substrate having the solid-state image pickup devices is held by adhesion.

10. The method for manufacturing a solid-state image pickup device module as set forth in claim 5, wherein the support holds the transparent substrate so that deflection of the transparent substrate is reduced.

11. The method for manufacturing a solid-state image pickup device module as set forth in claim 1, further comprising the step of: forming on the transparent substrate an IR cut coating that has the same size as that of the transparent substrate, before the step of processing a transparent substrate or before the step of cutting the transparent substrate.

12. The method for manufacturing a solid-state image pickup device module as set forth in claim 3, further comprising the step of:
temporarily fixing a support to the transparent substrate, before the step of cutting the transparent substrate,
wherein the support and the transparent substrate are temporarily fixed to each other via an adhesive whose adhesion is decreased in response to externally applied force.

13. The method for manufacturing a solid-state image pickup device module as set forth in claim 12,
wherein the adhesive contains (i) a foaming agent that generates bubbles in response to application of ultraviolet rays or heat or (ii) a material that becomes hardened in response to application of ultraviolet rays or heat so that adhesion of the material is decreased.

14. The method for manufacturing a solid-state image pickup device module as set forth in claim 6,
wherein the adhesive contains (i) a foaming agent that generates bubbles in response to application of ultraviolet rays or heat or (ii) a material that becomes hardened in response to application of ultraviolet rays or heat so that adhesion of the material is decreased.

15. The method for manufacturing a solid-state image pickup device module as set forth in claim 2, wherein,
at least (i) in the step of causing the transparent substrate thus processed and the substrate having the solid-state image pickup devices to be arranged so that the individual transparent substrates face the solid-state image pickup devices, respectively, or (ii) in the step of causing the first substrate on which the sealing agent is applied and the second substrate holding the individual transparent substrates to face each other so that the individual transparent substrates face the solid-state image pickup devices, respectively,
a peripheral part of the transparent substrate or the substrate having the solid-state image pickup devices is held.

16. The method for manufacturing a solid-state image pickup device module as set forth in claim 3, wherein,
at least (i) in the step of causing the transparent substrate thus processed and the substrate having the solid-state image pickup devices to be arranged so that the individual transparent substrates face the solid-state image pickup devices, respectively, or (ii) in the step of causing the first substrate on which the sealing agent is applied and the second substrate holding the individual transparent substrates to face each other so that the individual transparent substrates face the solid-state image pickup devices, respectively,
a peripheral part of the transparent substrate or the substrate having the solid-state image pickup devices is held.

17. The method for manufacturing a solid-state image pickup device module as set forth in claim 12, wherein,
at least (i) in the step of causing the transparent substrate thus processed and the substrate having the solid-state image pickup devices to be arranged so that the individual transparent substrates face the solid-state image pickup devices, respectively, or (ii) in the step of causing the first substrate on which the sealing agent is applied and the second substrate holding the individual transparent substrates to face each other so that the individual transparent substrates face the solid-state image pickup devices, respectively,
the transparent substrate or the substrate having the solid-state image pickup devices is held by adhesion.

18. The method for manufacturing a solid-state image pickup device module as set forth in claim 12,
wherein the support holds the transparent substrate so that deflection of the transparent substrate is reduced.

19. The method for manufacturing a solid-state image pickup device module as set forth in claim 2, further comprising the step of:
forming on the transparent substrate an IR cut coating that has the same size as that of the transparent substrate, before the step of processing a transparent substrate or before the step of cutting the transparent substrate.

20. The method for manufacturing a solid-state image pickup device module as set forth in claim 3, further comprising the step of:
forming on the transparent substrate an IR cut coating that has the same size as that of the transparent substrate, before the step of processing a transparent substrate or before the step of cutting the transparent substrate.
